(19) United States
(12) Patent Application Publication
(10) Pub. No.: US 2026/0044065 A1
(43) Pub. Date: Feb. 12, 2026

(54) METHOD AND DEVICE FOR MASK REPAIR

(71) Applicant: Carl Zeiss SMT GmbH, Oberkochen (DE)

(72) Inventors: Christian Preischl, Mainz (DE); Christian Felix Hermanns, Frankfurt (DE); Daniel Rhinow, Frankfurt (DE); Petra Spies, Mainz (DE)

(21) Appl. No.: 19/363,707

(22) Filed: Oct. 21, 2025

Related U.S. Application Data
(63) Continuation of application No. PCT/EP2024/060744, filed on Apr. 19, 2024.

(30) Foreign Application Priority Data
Apr. 21, 2023 (DE) 102023203694.0

(51) Int. Cl. G03F 1/22; G03F 7/00

(52) U.S. Cl. CPC G03F 1/22; G03F 7/70383

(57) ABSTRACT

The present invention relates to methods, to a device and to a computer program for processing of a lithography object. More particularly, the present invention relates to a method of removing a material, to a corresponding device and to a method of lithographic processing of a wafer, and to a computer program for performing the methods.

A method of processing a lithography object comprises: providing a first gas comprising first molecules; providing a particle beam on the object for removal of a first object material based at least partly on the first gas, wherein the first material comprises iridium.

### CROSS-REFERENCE TO RELATED APPLICATIONS

This application is a continuation of and claims benefit under 35 U.S.C. § 120 from PCT application PCT/EP2024/060744, filed on Apr. 19, 2024, which claims priority from German patent application DE 10 2023 203 694.0, filed on Apr. 21, 2023. The entire contents of each of these earlier applications are incorporated herein by reference.

### TECHNICAL FIELD

The present invention relates to methods, to a device and to a computer program for processing of a lithography object. More particularly, the present invention relates to a method of removing a material, to a corresponding device and to a method of lithographic processing of a wafer, and to a computer program for performing the methods.

### BACKGROUND

In the semiconductor industry, increasingly smaller structures are produced on a wafer in order to ensure an increase in integration density. Among the methods used here for the production of the structures are lithographic methods, which image these structures onto the wafer. The lithographic methods may comprise, for example, photolithography, ultraviolet (UV) lithography, DUV lithography (i.e., lithography in the deep ultraviolet spectral region), EUV lithography (i.e., lithography in the extreme ultraviolet spectral region), x-ray lithography, nanoimprint lithography, etc. Masks are usually used here as lithography objects (e.g., photomasks, exposure masks, reticles, stamps in the case of nanoimprint lithography, etc.), which comprise a pattern in order to image the desired structures onto a wafer, for example.

In the course of a lithographic method, a mask may be subject to high physical and chemical stresses (for example on mask exposure, mask cleaning, etc.). Accordingly, high demands are made on the stability of the mask materials. Over the course of time, particular mask materials have become established for particular mask structures (for example, tantalum or chromium for radiation-absorbing and/or phase-shifting mask structures). For example, the mask materials may be designed such that there is a low layer thickness of an absorber in the mask and/or a specific phase-shifting property of a mask structure. With advancing technical development in lithography, the high demands on the mask materials may, however, become even more severe. In order still to ensure resistant mask materials having desired radiation-absorbing and/or phase-shifting properties, alternative mask materials and the production of masks based thereon have recently been examined in the field of lithography.

Since mask faults generally cannot be ruled out in complex mask production, however, mask materials may also form as (local) mask faults on the mask (for example as defects, excess material, malformed material, overlying particles, etc.).

However, existing methods of processing masks have been designed exclusively for industrially long-established mask materials.

The problem addressed by the present invention is therefore that of optimizing the processing of lithography objects.

### SUMMARY

This general aspect is at least partly achieved by the various aspects of the present invention.

A first aspect of the invention relates to a method of processing a lithography object.

The method comprises providing a first gas comprising first molecules. The method may further comprise providing a particle beam on the object for removal of a first object material based at least partly on the first gas, wherein the first material comprises iridium.

One problem addressed by the invention is that of removing materials on a lithography object that are designed to be resistant to removal under chemical and/or physical stress.

There has recently been discussion as to whether parts of a lithography object should be produced from an iridium-containing material in order to do justice to current and future demands in lithography.

By virtue of the iridium-containing material, for example, object structures formed therefrom may have elevated chemical stability to the demands of lithography. An object structure may comprise, for example, a three-dimensionally configured geometry in terms of length, width and/or height, a topology step, an elevation, a depression in the object, or any topological variance in relation to a planar plane of the object. In addition, it is possible by use of iridium-containing material to achieve desired optical properties of the structures (for example desired radiation-absorbing and/or phase-shifting properties of the structures).

The iridium-containing material need not necessarily be present in an object structure, but may also be incorporated in any object layer in order to do justice to demands in lithography. For example, the iridium-containing material may also be present in a (for example, very substantially) planar object layer. For example, it is conceivable that the iridium-containing material is incorporated into specific functional object layers (for example, into a capping layer and/or as material of a reflective object layer, for example as material of a Bragg mirror). The iridium-containing material need not be limited, for example, to optical functions, but may also fulfil other functions (e.g., a mechanical and/or chemical function, for example, a protective function).

The iridium-containing material may, for example, have been designed specifically in order to explicitly prevent the removal of the first material under chemical/physical influences. The iridium-containing material may, for example, be designed so as to prevent removal/wear of mask structures formed therefrom even under sustained or regular chemical/physical stress. The iridium-containing material may, for example, be designed for the extreme conditions in lithography methods under which the object is to be used for lithography. For example, the object may be exposed to a (damaging) plasma during a lithography method. For example, it may be necessary for a lithography method to expose the object to a hydrogen environment (for example, for prevention of defects). In the case of lithographic exposure of the object, there may be release of a (parasitic) high-reactivity hydrogen plasma with free hydrogen radicals that can act on the material of the object. The plasma constitutes a high degree of chemical/physical stress on the object and can cause removal of material and damage to the material of the object (for example in a similar manner to plasma etching). However, the material-removing effect is undesirable in the lithography object, since this can adversely affect the properties of the object and hence the quality of the lithography method. Therefore, the iridium-containing material may be (explicitly) designed in order to assure high resistance of the first material to the material-removing effect of a plasma (for example, especially of the high-reactivity hydrogen plasma). Moreover, the object may be subjected to numerous other mechanical/chemical influences in lithography, which can damage the object (for example, in combination with the effect of plasma). For example, the other damaging influences may include severe temperature fluctuations, exposure radiation, and chemical reactions of the object with purge gases or subsequent cleaning processes. The iridium-containing material may therefore typically be designed to fundamentally counteract the totality of the damaging material-removing effects in lithography, such that mechanical/chemical wear and removal of the iridium-containing material is made more difficult.

The inventors have recognized that such an iridium-containing material can be removed in a particle beam-induced manner. By this approach, it can be made possible, for example, to process excess iridium-containing material (for example, to remove erroneous iridium-containing material). The basis of the inventive concept is accordingly to remove materials that are specifically designed to be resistant to removal via a particle beam-based process.

The inventors have hit on the unexpected finding that iridium-containing material in a lithography object can be removed with the aid of a provided gas and a provided particle beam (for example, via particle beam-induced etching). This was a surprising finding to the inventors since it was not foreseeable that the first material—resistant to the aggressive conditions of the lithography—can be processed in a particle beam-based manner or even removed (for example, without the use of a plasma). An additional factor that made it more difficult for the inventors to reach this finding was that the prevalent view was that iridium can be etched by wet-chemical means only by use of significantly heated (boiling) aqua regia.

In addition, it was also unexpected to the inventors in view of the resistant (iridium-containing) first material that, in the case of particle beam-based removal of the first material, the provision of a gas comprising first molecules is sufficient. There is not necessarily any need in accordance with the invention to resort to a complex gas mixture (for example comprising different types of molecule designed for the resistant material). This can ensure that complexity in particle beam-reduced removal is reduced, as a result of which, for example, easier process control in the method according to the invention is possible (since, for example, the providing of a single gas constitutes a lesser demand on technical implementation than the providing of a gas mixture of, for example, two or more different gases). The invention accordingly enables processing of lithography objects having materials composed of a (resistant) iridium-containing material. The first material may be designed, for example, such that it withstands, essentially without change, at least 20, at least 50, at least 100 or even at least 1000 cleaning cycles that are undertaken in a (UV, e.g., EUV or DUV) mask cleaning operation (such that for example, in the case of a mask having the first material as part of a pattern element of the mask, no printable errors are generated by the cleaning cycles).

The lithography object as described herein may comprise a lithography mask for example. The lithography mask may be designed, for example, such that it can be used in lithography for the production of semiconductor-based chips (for example, on exposure of a semiconductor-based wafer). The lithography mask may also include any type of lithography mask that can image an image based on a source of electromagnetic radiation (of any wavelength) and a pattern encompassed in the lithography mask. The image may comprise a transformation of the pattern. The lithography mask may comprise, for example, an EUV mask, a DUV mask, a UV mask, an x-ray lithography mask, a binary mask, a radiation-absorbing and/or phase-shifting mask, etc. The lithography object may comprise, for example, an object for optical lithography (i.e., a lithography method based on an exposure radiation). In addition, the lithography mask may also comprise a nanoimprint lithography stamp. In addition, the object may comprise a lithography mask that can image a pattern based on a source of particles.

The lithography object may also comprise a mask blank in one example. In the lithographic industry, mask blanks are a known starting material for a mask. For example, the mask blank may not comprise any imaging structures like the mask itself, but may comprise the layer material thereof.

In one example of the method, the first gas may be provided locally on the object. For example, the first gas can be provided locally above the object via a gas conduit. The local providing may comprise, for example, a concentration gradient of the first gas above the object. For example, the local providing can enable presence of the first gas in a locally confined object region, or cause a particle beam-induced reaction there. There is thus no need to (necessarily) expose the whole object to the first gas.

In one example, the first gas (and/or the particle beam) may be provided (for example, essentially only) in a working region of the object. This working region may comprise, for example, a local region of the lithography object. For example, the first gas may be provided (for example, essentially only) within a region of 5 mm×5 mm or 3 mm×3 mm. However, it is also conceivable that the working region comprises the entire lithography object. The working region may also include any areal dimension, shape and/or (three-dimensional) geometry. For example, the working region may be within an order of magnitude associated with a particular measurement of the object. For example, the particular measurement may comprise a critical dimension CD of a pattern element of the object.

The pattern element may comprise, for example, part of a mask structure, part of the layers of a mask structure and/or the mask structure itself. A pattern element may comprise, for example, an object structure that achieves a desired effect in lithography by virtue of a defined spatial configuration. For example, the pattern element may be configured to create a pattern in lithography. For example, the pattern element may also be configured to adjust an optical effect (for example an adjustment of contrast).

The critical dimension CD may comprise, for example, a defined structure width of the pattern element or else a defined distance between two (characteristic) pattern elements. The working region may, for example, form an area A over the critical dimension CD of the pattern element (for example, A may correspond to a function of the critical dimension CD, with A=f(CD); for example, A may be proportional to the critical dimension). In addition, the first material may be removed within the working region such that the first material is not necessarily removed over the entire area of the working region, but is removed (locally) in a subregion of the working region. Alternatively, the removing within the working region can be effected such that the first material is removed over the entire area of the working region. In addition, the first gas may be provided in a controlled manner in a subregion of the working region (for example, via a locally positionable gas conduit with a gas nozzle). It is likewise possible for the particle beam to be provided in that it is directed onto a subregion of the working region such that the particles of the particle beam are incident on the subregion. In addition, the method may comprise controlled specific local control and/or focusing of the particle beam in the subregion or within the working region (in order, for example, to locally control reaction of the particle beam-induced etching).

In one example, in the method in the first aspect, the first material is fully removed in the working region. For example, it is possible by use of the method for the first material no longer to be present in the working region after the removal. The first material may accordingly also be removed without residue by use of the method.

In one example, the first material comprises a layer material of the object. For instance, the first material may be in any portion of the object.

As described herein, the first material may comprise, for example, a layer material of a (spatially defined) object structure. The first material may also comprise, for example, a layer material of any object layer. For example, the layer material may be part of a capping layer of the object. For example, there may be one or more structures adjoining the capping layer. For example, the layer material may also be part of a reflective layer stack of the object.

In one example, the first material comprises a layer material of a pattern element of the object. The first material may comprise, for example, a portion of a pattern element of the object. The first material may also comprise, for example, a portion of a defective pattern element of the object.

In one example, the first material comprises a radiation-absorbing and/or phase-shifting layer material of the object. For example, the radiation-absorbing and/or phase-shifting layer material may be part of a pattern element of the object.

In one example, the radiation-absorbing (and/or phase-shifting) layer material may be capable of absorbing radiation associated with the object. For example, this radiation associated with the object may comprise electromagnetic radiation with a particular wavelength which may be used in a lithography method for which the object is designed. For example, the radiation associated with the object may correspond to an exposure radiation for the object in the lithography method. The particular wavelength of the exposure radiation may be regarded as the lithography wavelength of the object.

In one example, in the method, the layer material corresponds to a material of an absorption layer of the pattern element. The absorption layer may comprise the position of the pattern element which is explicitly set up for the absorbing of the radiation of lithography wavelength. The (iridium-containing) first material may be designed, for example, to enable a low layer thickness of the absorption layer.

In one example, the lithography object comprises an EUV mask for an EUV lithography method, wherein the lithography wavelength (i.e., the wavelength of the exposure radiation) in this case may be 13.5 nm. In addition, the radiation may relate, for example, to a DUV lithography method (with, for example, lithography wavelength 193 nm or 248 nm), an i-line lithography method (with, for example, lithography wavelength 365 nm), or any other lithography method (with, for example, a different lithography wavelength) depending on the object.

In one example, the first material has an intrinsic material parameter which can be used to conclude a significant (e.g., high) absorption of the lithography wavelength of the object (e.g., a coefficient of absorption, a magnitude of absorption, an imaginary part of the refractive index of the first material).

It is likewise conceivable that the significant absorption may be defined via a (low) reflectivity of the first material. For example, the reflectivity of the first material (for example, in the region of the lithographic wavelength) may comprise not more than 25 percent, preferably not more than 20%, more preferably not more than 17%. In addition, the first material may comprise a material which is typically present in the object in order to absorb the lithography wavelength (e.g., a material corresponding to an absorption layer (for example, to a pattern element) of the object).

In a further example, the first material has not just one intrinsic material parameter per se that can be used to conclude a significant absorption. In addition, the first material may be geometrically configured such that it can effectively absorb the radiation associated with the object in a local area of the object. For example, the first material, in a (local) area of the object, may be formed geometrically such that it causes significant absorption of radiation of the lithography wavelength via the absorbing material property thereof and the geometric structure thereof. In this case, the first material in the (local) area may make an imaging contribution in a lithography method since there is an actual (i.e., effective) absorption of the radiation of the lithography wavelength. The geometry of the first material may be defined, for example, via the layer thickness of the material, or via a distance that would be covered by radiation of lithography wavelength in a lithography method through the first material (i.e., an absorption distance). The absorption distance may take account, for example, of the optical diffraction of the radiation of lithography wavelength or a vector of incidence of the exposure radiation. For example, the method may comprise not removing a very thin layer of an absorbing material (i.e., an intrinsically absorbing material), since that thin layer in geometric terms is unable to significantly absorb the radiation of lithography wavelength and hence does not make an actual (i.e., effective) imaging contribution in a corresponding lithography method. For example, the significant absorption may be defined or calculated by the layer thickness or absorption distance of the first material: The layer thickness of the first material may be at least 20 nm, preferably at least 35 nm, more preferably at least 50 nm, most preferably at least 60 nm. The layer thickness of the first material may alternatively be less than 60 nm, for example, less than 50 nm or less than 35 nm. Significant absorption may also be described, for example, in that the intensity of the radiation of lithography wavelength is attenuated by 70%, preferably 80%, most preferably 90%, in a lithography method (across the first material).

In one example, the extinction coefficient β of the first material (for example, at the lithography wavelength) may comprise a value of at least 0.038, at least 0.04, at least 0.041, or at least 0.042.

In one example, the extinction coefficient β of the first material (for example, at the lithography wavelength) may comprise a value of at most 0.05, at most 0.049, at most 0.048, or at most 0.047.

In one example, the extinction coefficient β of the first material (for example, at the lithography wavelength) may comprise a value between 0.038 and 0.05, between 0.04 and 0.049, between 0.041 and 0.048, or between 0.042 and 0.047.

In one example, the phase-shifting (and/or radiation-absorbing) layer material may be capable of shifting the phase of the radiation associated with the object. For example, the (iridium-containing) first material may also be designed to enable a phase-shifting property of a pattern element of the lithography object. In one example, the object may comprise a phase-shifting mask for EUV lithography.

In one example, the dispersion coefficient 8 of the first material (for example, at the lithography wavelength) may comprise a value of at least 0.08, at least 0.09, at least 0.091, or at least 0.092.

In one example, the dispersion coefficient δ of the first material (for example, at the lithography wavelength) may comprise a value of at most 0.12, at most 0.11, at most 0.1, or at most 0.099.

In one example, the dispersion coefficient δ of the first material (for example, at the lithography wavelength) may comprise a value between 0.08 and 0.12, between 0.09 and 0.11, between 0.091 and 0.1, or between 0.091 and 0.099.

In one example, the first gas may be regarded as a main etching gas for the removal of the first material. The first gas may be designed, for example, such that it has a substantial influence on the etching characteristics of the first material. For example, the molecules of the first gas may be chosen such that they bring about an etching/removing effect on the first material. The first molecules may also be chosen such that they bring about an etching/removing effect on the first material in conjunction with a reaction which is induced by the particle beam.

In one example, the first molecules may comprise a halogen atom. The inventors have recognized that a gas especially suitable for the removing of the (iridium-containing) first material is one comprising molecules including a halogen. Such a first gas (i.e., a substantial etching gas) in conjunction with the particle beam provided can remove the resistant first material advantageously in a technically desirable manner. For example, such a first gas can avoid removal residues, long etching times, inhomogeneous material removal in the method in the first aspect.

In one example, the halogen atom may comprise at least one of the following: fluorine, chlorine, bromine, iodine. For example, the first molecules may include fluorine. For example, the first molecules may also include chlorine. The first material may thus be removed by particle beam induction using chlorine chemistry and/or using fluorine chemistry.

In one example, the first molecules may comprise a halogen compound. For example, the halogen compound may comprise a chemical compound including at least one halogen atom, where the halogen atom enters into a chemical compound with at least one further chemical component (for example, any further chemical element or atom and/or a further chemical substance group/substance compound, etc.). In one example, the halogen compound may comprise exclusively halogens of the same type (for example, the first molecules may comprise F₂, Cl₂, Br₂, etc.).

In one example, the first molecules may comprise a noble gas halide. For example, the noble gas halide may comprise a chemical compound including at least one halogen atom and at least one noble gas atom.

In one example, the noble gas halide comprises at least one of the following: xenon difluoride, XeF₂, xenon dichloride, XeCl₂, xenon tetrafluoride, XeF₄, xenon hexafluoride, XeF₆. The inventors have recognized here that such noble gas halides too (e.g., xenon difluoride in particular), in the context of the method in the first aspect, can advantageously remove the resistant first material in a technically desirable manner.

In a further example, the first molecules comprise a quadrupole moment (or a multipole moment with at least four poles) of greater than zero. For example, xenon difluoride may have a quadrupole moment greater than zero.

In one example, the first molecules comprise polar molecules. It has been found that polar molecules having a dipole moment may be suitable in principle for the process. In a further example, the first molecules may alternatively comprise nonpolar molecules. The invention is also based on the concept that nonpolar molecules without a dipole moment may also be suitable in principle for the process. In an additional example, the first molecules comprise triatomic molecules. According to the invention, there is not necessarily any need for complex compounds having more than three atoms per molecule for a suitable method in the first aspect.

In one example, the first material may also include at least one second element. The second element may be regarded as part of any substance included in the first material (i.e., the second element may, for example, comprise part of a compound, a chemical element, etc.). The first material accordingly need not necessarily be formed exclusively from iridium. The first material may also be described here (stoichiometrically) in the form of IrₐZ_{b} with a>0, b≥0, where Z represents the at least second element (or one or more further chemical elements).

In one example, the iridium content of the first material may be at least 0.1 atom percent (at %).

For example, the iridium content of the first material may comprise at least 1 atom percent, at least 5 atom percent, at least 10 atom percent, at least 20 atom percent, at least 30 atom percent, at least 40 atom percent or at least 45 atom percent.

In one example, the iridium content of the first material may comprise at least 50 atom percent, at least 70 atom percent, at least 80 atom percent, or at least 90 atom percent.

In one example, the iridium content of the first material may comprise 100 atom percent or not more than 99.9 atom percent.

For example, the iridium content of the first material may comprise at most 90 atom percent, at most 80 atom percent, at most 70 atom percent, at most 60 atom percent, at most 50 atom percent or at most 40 atom percent.

In one example, the iridium content of the first material may comprise at most 30 atom percent, at most 20 atom percent, at most 10 atom percent, at most 5 atom percent or at most 2 atom percent.

In one example, the iridium content of the first material may comprise a value between 0.1 at % and 99.9 at %.

In one example, the iridium content of the first material may comprise a value between 1 at % and 99.9 at %, between 5 at % and 99.9 at %, between 10 at % and 99.9 at %, between 20 at % and 99.9 at %, between 30 at % and 99.9 at %, between 40 at % and 99.9 at %, between 50 at % and 99.9 at % or between 60 at % and 99.9 at %.

In one example, the iridium content of the first material may comprise a value between 0.1 at % and 90 at %, between 0.1 at % and 80 at %, between 0.1 at % and 70 at %, between 0.1 at % and 60 at %, between 0.1 at % and 50 at %, between 0.1 at % and 40 at % or between 0.1 at % and 30 at %.

The unit “atom percent,” as described herein, may relate to a molar proportion of the corresponding material, where atom percent indicates, for example, the relative number of particles (e.g., iridium atoms) in relation to the total number of particles of the substance (for example, total number of atoms of the first material). The atomic percentage may be detected, for example, via secondary ion mass spectrometry, SIMS, and/or Auger electron spectroscopy and/or x-ray photoelectron spectroscopy, XPS (and also, for example, via photoelectron spectroscopy, PES).

In one example, the second element may comprise at least one of the following: a metal, a semiconductor. Likewise possible is a combination of metal and semiconductor.

The metal may comprise, for example, a heavy metal, a light metal, a transition metal, a precious metal, a base metal and/or a metal alloy.

In one example, the semiconductor comprises a semimetal and/or a compound semiconductor. The semiconductor may comprise direct and/or indirect semiconductors. For example, the semiconductor may comprise at least one of the following: silicon (Si), germanium (Ge), boron (B), arsenic (As), gallium arsenide (GaAs), aluminium gallium arsenide (AlGaAs), silicon carbide (SiC), gallium nitride (GaN).

In one example, the second element may include at least one of the following: tantalum, ruthenium, antimony. In one example, the first material comprises iridium and ruthenium. In a further example, the first material comprises iridium and tantalum. In a further example, the first material comprises iridium and antimony. It is also conceivable that the first material comprises iridium, tantalum and ruthenium. In a further example, the first material comprises iridium, tantalum, ruthenium and antimony.

In one example, the second element may comprise at least one nonmetal.

In one example, the second material (or the nonmetal) may comprise oxygen and/or nitrogen.

For example, the nonmetal may also comprise at least one of the following: phosphorus, hydrogen, carbon, a halogen (e.g., bromine, fluorine, chlorine etc.).

In one example, the iridium may enter into a chemical compound with the second element (or with the at least one second element). The chemical compound may comprise, for example, a binary, ternary and/or quaternary chemical compound.

In one example, the method may further comprise: providing a second gas comprising second molecules, wherein the removing of the first material is also based at least partly on the second gas.

The second gas described herein may be regarded in this context as additive gas in relation to the main etching gas (i.e., the first gas). The second gas can further influence the removing or particle beam-induced etching of the first material as additive gas and, for example, more accurately adapt process parameters/results (e.g., etch rate, anisotropy factor, selectivity, sidewall angle, surface roughness, etc.). In principle, the molecules described herein for the providing of the first gas may also be applicable to the providing of the second gas, and vice versa.

In one example, a dipole moment of the second molecules may comprise a value between 1.6 D and 2.1 D, preferably between 1.7 D and 2 D, more preferably between 1.8 D and 1.95 D, most preferably between 1.82 D and 1.9 D.

The inventors have recognized that molecules having such dipole moments can be advantageous in the removing of the first material. In the particle beam-based removal, what is typically required is a defined (local) gas concentration over a particular period of time, in order to allow the removal reaction to run in a defined manner. On account of chemical and/or physical interactions in the removing of the first material, however, the defined (local) gas concentration may vary to a technically undesirable degree. This is of increased importance especially in the case of use of a more complex gas mixture comprising at least two gases (e.g., the first gas and the second gas). This is associated with elevated demands on the maintenance of the defined (local) gas concentration. For example, it is possible here for an increased degree of (local) depletion of the second gas (and/or of the first gas) to occur within the working region, such that the removing of the first material can be influenced in an unwanted manner. The inventors have recognized here that the using of second molecules with the dipole moments specified herein enables optimized conditions in the configuration of the defined (local) gas concentration in the use of the first and second gases. It is thus also possible to optimize the removing of the first material in a controlled manner.

In one example, the method comprises taking account of the dipole moment of the second molecules as a parameter in the removing of the first material. For example, the dipole moment of the second molecules may define a process parameter (for example, a gas volume flow rate of the first and/or second gas) in the removing operation. For example, the gas volume flow rate may be selected depending on the dipole moment.

In one example, the method comprises providing the first gas and the second gas at least partly simultaneously. For example, the first gas and the second gas may be introduced simultaneously into the environment of the working region or into the environment of the object, for example, during the removal of the first material. This may also comprise the (at least partial) presence of a first gas volume flow rate of the first gas and of a second gas volume flow rate of the second gas during the removal, such that the presence of both gases in the environment of the working region/object is assured. It may be possible here, for example, that the first and second gas volume flow rates are essentially identical. In other examples, they may alternatively be different. The simultaneous provision of the first and second gases may also comprise variation of the first gas volume flow rate and of the second gas volume flow rate (in the removal of the first material).

In one example, the method comprises providing the first gas and the second gas at least partly with a time interval. For example, it may be necessary for the removal of the first material for only one of the two gases to be provided or introduced in the environment of the working region/object in a method step of removing. For example, it may be necessary for commencement of the removing of the first material for the first gas only (or the second gas) to be introduced at first into the environment of the working region/object. Subsequently, the second gas (or the first gas) may be fed in or provided at a later juncture. In addition, it is also conceivable that, during the removing, there is stepwise alternation between the (exclusive) providing/introducing of the first gas (without the second gas) and the (exclusive) providing/introducing of the second gas (without the first gas). Furthermore, it is also possible that an end of the process of removing the first material comprises the exclusive providing/introducing of one of the two gases. For example, it is conceivable that an end of the process is defined by the exclusive providing/introducing of the second gas.

In one example, the second molecules may comprise water, H₂O, and/or heavy water, D₂O. Thus, for the removing of the resistant first material, water and/or heavy water has been found to be an advantageous additive gas. For example, such an additive gas can also optimize the selectivity of the removing of the first material with respect to another material. In a particularly advantageous example, the method comprises XeF₂ as the first gas and H₂O as the second gas. In a further example, the second molecules of the second gas may also comprise semi-heavy water, HDO.

In a further example, the second gas (or the second molecules) may comprise an oxygen-containing component, a halide and/or a reducing component. The oxygen-containing component may include, for example, an oxygen-containing molecule. For example, the oxygen-containing component may comprise at least one of the following: oxygen (O₂), ozone (O₃), hydrogen peroxide (H₂O₂), dinitrogen monoxide (N₂O), nitrogen monoxide (NO), nitrogen dioxide (NO₂), nitric acid (HNO₃). The halide may include, for example, at least one of the following: Cl₂, HCl, XeF₂, HF, I₂, HI, Br₂, HBr, NOCl, NOF, ClNO₂, FNO₂, PCl₃, PCl₅, PF₃, PF₅. The reducing component may comprise here a molecule having a hydrogen atom. For example, the reducing component may comprise at least one of the following: H₂, NH₃, (NH₂)₂, CH₄. In one example, the second gas may comprise water (and/or heavy water) and nitrogen dioxide.

In one example, the first material may be removed selectively, such that a second material of the object is essentially not removed. For example, the method may be designed such that, in the removal according to the invention (for example, based on particle beam-induced etching), there is selectivity of removal (for example, etching selectivity) for the first material over the second material. The selectivity may enable, for example, removal of the second material at a lower removal rate than the first material when the second material is subjected to the method. Accordingly, in the method, a defined selectivity is established (for example, an elevated etching selectivity). This can be assured, for example, via a suitable choice of the first and/or second gas and suitable gas parameters of the first and/or second gas (e.g., gas mass flow rate, gas pressure, gas concentration, etc.). For example, it is especially possible to use the choice of the second gas (e.g., water and/or heavy water, as described herein) and the gas parameters of the second gas to adjust the selectivity of removal of the first material with respect to the second material. The method can also be effected in such a way that there is essentially no physical/chemical stress on the second material.

In one example, the second material may also comprise a material at any site on the lithography object, and also a material within the working region (described herein). Also conceivable as second material is a material that would in principle be subjected to the material-removing action of the process. For example, this may comprise exposure of the second material to the first (or second) gas during the method and/or presence in the relatively close (or else immediate) environment of the particle beam. For example, the second material may adjoin the first material or be mechanically coupled to the first material (for example, including indirectly via an intervening material). In this case, it is conceivable that the removing of the first material is associated with exposure of a surface of the second material, such that the second material would be subjected to the material-removing effect of the method. According to the invention, the removing of the second material can be counteracted via the selectivity of the method. The second material, in a typical application of the method, may, for example, be part of a layer of the object adjoining the first material (directly or indirectly). For example, the object may have a characteristic layer structure in which a capping layer adjoins a reflective layer stack (e.g., a Bragg mirror). The characteristic layer structure may also comprise a buffer layer adjoining the capping layer. There may additionally be an absorption layer adjoining the buffer layer. In one example, a portion of the absorption layer may comprise the first material (to be removed) in the method. The method may accordingly be configured with such a selectivity that the second material comprises the material of the buffer layer, the material of the capping layer and/or the material of the reflective layer stack. In one example, the selectivity is configured such that the second material explicitly comprises the material of the capping layer of the reflective layer stack of the object. This can enable controlled ending of the method via the reduced removal rate of the capping layer, without attacking the reflective layer stack. The capping layer may accordingly function as a removal stop (e.g., etching stop), such that it is possible to avoid damage to the reflective layer stack that would be associated with damage to the optical properties of the object.

The method can be effected in that the selectivity of the removing of the first material with respect to the second material is at least 2:1. In one example, the selectivity of the removing of the first material with respect to the second material is at least 7:1, preferably at least 15:1, more preferably at least 25:1, most preferably at least 50:1.

In one example, the method may comprise removing at least one intermediate material disposed between the first material and the second material. As described herein in relation to the characteristic layer structure, the intermediate material may comprise, for example, part of the buffer layer of the object. In addition, it is also conceivable that the at least one intermediate material comprises part of the buffer layer and part of the capping layer of the object. The intermediate material need not necessarily comprise the properties of the first material (or of the second material) that are specified herein.

In one example, the method comprises removing at least one surface material of the object.

The surface material may comprise, for example, a material of the object having a surface accessible to the first gas and/or the second gas, and to the particle beam (for example, an exposed surface of the object). The surface material may comprise any material, and is not restricted to the substances and proportions of substances of the first and second material as specified herein. The surface material may be removed here, for example, in order to (at least partly) expose the first material disposed below it for the method according to the invention. In relation to the characteristic layer structure of the object as described herein, the surface material may, for example, be part of a surface layer adjoining the absorption layer (for example, with respect to the buffer layer). The surface layer may comprise, for example, an antireflection layer, an oxide layer, a passivation layer.

In one example, the method is effected in such a way that a defect of the object is repaired. For example, the method may comprise repairing an opaque defect of the object.

An opaque defect here may be a faulty site on the lithography object that should actually not be opaque, i.e., clear, according to the design of the object (e.g., transparent or designed such that there is no specific absorption for a radiation of a particular wavelength, for example, the lithography wavelength). An opaque defect may also be regarded as a faulty site on the object which is not supposed to comprise any material of a pattern element according to the design of the object, but an (unwanted) material is present at the site. The (unwanted) material present may, for example, comprise a material of the pattern element, although it is also conceivable that it is a different (unwanted) material having a radiation-absorbing and/or phase-shifting effect.

A clear defect, by contrast, is a faulty site on the lithography object that should actually be opaque according to the design of the object (e.g., non-transparent or strongly absorbing for a radiation of a particular wavelength, for example, the lithography wavelength). A clear defect may also be regarded as a faulty site on the object which is supposed to comprise a material of a pattern element according to the design of the object, but no material is present at the site, or the material of the pattern element is absent. In particular, opaque may be defined in relation to a lithography method for the object. For example, the lithography object may comprise an EUV mask for an EUV lithography method, in which case “opaque” may refer in this case to the lithography wavelength of 13.5 nanometers. It is also conceivable that “opaque” relates to a DUV lithography method (at a lithography wavelength, for example, of 193 nanometers or 248 nanometers), an i-line lithography method (at a lithography wavelength, for example, of 365 nanometers), or any other lithography method depending on the object. In addition, an opaque defect may comprise, for example, a faulty site having opaque material of a layer of a lithography mask (for example, this may comprise a layer designed as a layer for an opaque pattern element of the object). The method here may comprise removing the first material such that the faulty site is no longer opaque.

For example, the repair of the defect may comprise firstly localizing the defect (for example, via a scanning electron microscope, an optical microscope, etc.). It is possible here to define the working region which is used for the removing of the first material on the basis of at least one characteristic of the localized defect (for example, based on a position, shape, size, type of defect, etc.). The remedying of the defect in the object may further comprise producing a repair mould encompassing the defect. In one example, the repair mould may serve as the working region for the method specified herein. The repair mould may have, for example, a pixel pattern, which can enable localization of a defect site. The pixel pattern may, for example, be designed such that it follows the outline of the defect, such that every pixel in the pixel pattern corresponds essentially to a site in the defect and hence constitutes a defect pixel. In another example, the pixel pattern has a fixed geometric shape (e.g., a polygon, a rectangle, a circle, etc.) which fully encompasses the defect, in which case not every pixel necessarily constitutes a defect site. It is possible here for the pixel pattern to include defect pixels corresponding to a defect site, and non-defect pixels corresponding to a site which does not cover part of the defect. In one example, the method comprises directing the particle beam at least onto a defect pixel of the pixel pattern of the repair mould in the producing of the material. In addition, the particle beam may be configured such that it can be directed onto any defect pixel in the removing of the first material (or the removing of the second material). This can ensure that the removing of the first (or second) material is locally restricted to the defect pixel and hence only the defect is processed.

In a further example, the method may be used in processing of the object which comprises local production of a material. The processing, and the local production of material, can be effected, for example, in the context of defect processing in an object (for example, in a repair of a clear defect and/or a defective site, in a removal of a particle, etc.). The method described herein can also be used in such a method.

In one example, the object comprises an EUV mask and/or a DUV mask. For example, the characteristic layer structure described here may correspond to a layer structure of an EUV mask.

In one example, the particle beam may comprise an electron beam. For example, the removing described herein, in the context of the method, may comprise electron beam-induced etching (known, for example, by the term (F)EBIE—(focused) electron beam induced etching).

However, it is also conceivable that the particle beam comprises an ion beam (for example, of gallium ions, helium ions, etc.). For example, the removing of the first material may be based on ion beam-induced machining/etching (e.g., focused ion beam (FIB) milling).

In addition, use of multiple particle beams as particle beam is also conceivable.

In one example, the method may further comprise: determining an endpoint of a removing of a material based at least partly on detecting of electrons that are released from the working region. The electrons detected may comprise, for example, primary electrons and/or secondary electrons.

In one example of the method, a material may be removed at least partly over a predetermined period of time. For example, the duration for a parameter space of the method may be determined experimentally (for example, by means of performing the method with multiple durations in order to determine when a material (for example, with a particular thickness) has been removed). For example, the predetermined duration may correspond to a predetermined thickness of the material.

In one example, the method can be effected in such a way that a sidewall angle (of an edge, for example, of a structure) of the first material is adapted in a controlled manner with regard to a plane of a further material (for example, with regard to a plane of the second material). The sidewall angle may be based, for example, on the plane of a layer disposed beneath the first material, or else on the (planar) plane of the object.

For example, the sidewall angle may comprise at least 70°, at least 74°, at least 78°, at least 80°, at least 85°. For example, the sidewall angle may comprise at most 90°, at most 88°, at most 85°, at most 80°. For example, the sidewall angle may comprise a value between 70° and 90°, preferably between 74° and 90°, more preferably between 78° and 90°, most preferably between 80° and 90°.

In one example, in the method in the first aspect, the particle beam is based at least partly on an acceleration voltage of less than 3 kV, preferably less than 1 kV, more preferably less than 0.8 kV, most preferably less than 0.6 kV. In one example, the particle beam is also based on an acceleration voltage of at least 0.1 kV, preferably at least 0.15 kV, even more preferably at least 0.2 kV, most preferably at least 0.3 kV. In one example, the acceleration voltage of the particle beam comprises a value between 0.1 kV and 3 kV, between 0.15 kV and 1 kV, between 0.2 kV and 0.8 kV, or between 0.3 kV and 0.6 kV.

The method in the first aspect (as described herein) can advantageously be effected in these ranges of acceleration voltage. For example, in this parameter space, the first material can advantageously be removed with the particle beam.

In addition, it is also conceivable that the particle beam is based on an acceleration voltage of less than 30 kV, preferably less than 20 kV. In one example, an acceleration voltage between 3 kV and 30 kV may be employed for imaging purposes within the process (in the case of imaging before after the removal and/or imaging during the removal).

In one example, the particle beam comprises a current of at least 1 pA, at least 5 pA, at least 10 pA, at least 20 pA, at least 25 pA, at least 50 pA.

In one example, the particle beam comprises a current of at most 100 pA, at most 80 pA, at most 60 pA or at most 50 pA.

In one example, the particle beam comprises a current having a value between 1 pA and 100 pA, preferably between 5 pA and 80 pA, most preferably between 10 pA and 60 pA.

In one example, the method is effected in such a way that the exposing of the second material (via the removing of the first material) gives a surface of the second material having a square roughness, RMS, of less than 3 nm, preferably less than 2 nm, more preferably less than 1 nm, most preferably less than 0.5 nm.

A second aspect relates to a lithography object, wherein the object has been processed by a method in the first aspect. It is possible, for example, via an optical analysis of the object, to detect whether the object has been processed by a method in the first aspect. For example, for the lithography object, an optical analysis may initially have been conducted, or may be undertaken (for example, in the course of defect qualification of the object, for example, after production of the object and/or in the case of introduction of the object into a semiconductor works). The optical analysis may be based, for example, on an optical or particle-based microscope (for example, on a mask metrology device, a mask microscope) and, for example, an imaging operation. In the processing of the object in one example of the first aspect, after the initial analysis, the first material may have been removed as described herein. The removal of the first material can be detected via a repeated visual analysis (for example, in the course of a repair check or another defect qualification). The detection may be effected, for example, via a comparison of the initial visual analysis with the repeated visual analysis (for example, via a comparison of the corresponding images). In addition, the detection in the method may also be based on a material analysis of the object (for example, Auger spectroscopy, x-ray spectroscopy, etc.), which, for example, is executed in a supplementary manner with the initial or repeated visual analysis.

A third aspect relates to a method for processing a semiconductor-based wafer, comprising: a lithographic transfer of a pattern associated with a lithography object to the wafer, wherein the object has been processed using a method in the first aspect.

The lithographic transfer may comprise a lithography method for which the object is designed (e.g., EUV lithography, DUV lithography, i-line lithography, etc.). For example, the method in the third aspect may comprise providing a beam source of electromagnetic radiation (e.g., EUV radiation, DUV radiation, i-line radiation, etc.). This may additionally comprise a provision of a developable lacquer layer on the wafer. The lithographic transfer may also be based at least in part on the radiation source and the provision of the developable lacquer layer. It is possible, for example, by use of the radiation from the radiation source to image the pattern onto the lacquer layer (in a transformed form).

The methods described herein may, for example, be recorded in written form. This can be achieved, for example, by use of a digital file, analogously (for example, in paper form), in a user handbook, in a formula (recorded, for example, in a device and/or a computer at a semiconductor factory). It is also conceivable that a written protocol is compiled on execution of one of the methods described herein. The protocol may enable, for example, proof of the execution of the method and details thereof (for example, the formula) at a later juncture (for example, in the course of a fault assessment, a material review board, an audit, etc.). The protocol may comprise, for example, a protocol file (i.e., log file) which can be recorded, for example, in a device and/or computer.

A fourth aspect relates to a computer program comprising instructions for performing a method in the first aspect and/or in the third aspect.

A fifth aspect relates to a device for processing a lithography object, comprising: means of providing a first gas; means of providing a particle beam on the object. The device may comprise a memory comprising a computer program which, when executed, causes the device to perform a method in the first aspect.

For example, the device may comprise means of executing a computer program (e.g., a computer system, a computation unit, etc.).

For example, the computer program may comprise a computer program in the fourth aspect, programmed on the device. The device may, for example, store instructions in the computer program, where the stored instructions are executed by use of the computer system, and the corresponding means cause the device to execute the method in the first aspect.

The device may correspond, for example, (essentially) to a scanning electron microscope that can provide an electron beam as particle beam on the object. The scanning electron microscope may be configured such that it can provide the gases described herein. The first gas (and/or the second gas) may be stored, for example, in corresponding reservoir vessels and be guided via a gas supply system (e.g., a gas conduit with a gas nozzle) onto a working region of the object. The device may further include a closed-loop control system set up to perform the method in an automated manner.

Alternatively, it is also possible for the computer program to be stored elsewhere (e.g., in a cloud) and for the device to merely have means for receiving instructions that arise from executing the program elsewhere. Either way, this may allow the method to run in automated or autonomous fashion within the device. Consequently, it is also possible to minimize the intervention, for example, by an operator, and so it is possible to minimize both the costs and the complexity when processing masks.

### DESCRIPTION OF DRAWINGS

The following detailed description describes technical background information and working examples of the invention with reference to the figures, in which:

FIG. 1 gives a schematic illustration in a top view of an illustrative repair situation for a lithography object.

FIG. 2 shows a schematic diagram of an illustrative method of the invention.

FIGS. 3A-3C give in a schematic illustration, in a cross section, by way of example, operations in a method of the invention.

FIG. 4 shows a schematic view of an illustrative device of the invention.

### DETAILED DESCRIPTION

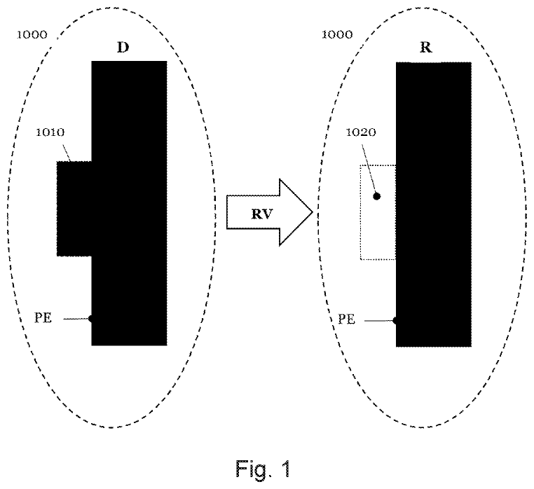

FIG. 1 gives a schematic illustration in a top view of an illustrative repair situation for a lithography object. The lithography object may comprise here a lithographic mask suitable for any lithography method (e.g., EUV lithography, DUV lithography, i-line lithography, nanoimprint lithography, etc.). In one example, the lithographic mask may comprise an EUV mask, a DUV mask, an i-line lithography mask and/or a nanoimprinting stamp. In addition, the lithography object may comprise a binary mask (e.g., a chromium mask, an OMOG mask), a phase mask (e.g., a chromium-free phase mask, an alternating phase mask (e.g., a rim phase mask)), a half-tone phase mask, a tritone phase mask and/or a reticle (for example, with pellicle). The lithographic mask may be used, for example, in a lithography method for the production of semiconductor chips.

The lithography object may comprise, for example, (unwanted) defects. For example, a defect may be caused in the production of the object. In addition, a defect may also be caused by (lithography) processing of the object, a process deviance in the (lithography) processing, transport of the object, etc. On account of the usually costly and complex production of an object for lithography, the defects are therefore usually repaired.

In the working examples described herein, for illustrative purposes, an EUV mask is frequently employed here as an example of a lithography object. However, rather than the EUV mask, any lithography object is conceivable (for example, as described herein).

FIG. 1 can show, in schematic form, in a top view, two local states D, R of a detail 1000 of an EUV mask in the course of a repair of a defect in the mask. The detail 1000 shows part of a pattern element PE of the EUV mask. The pattern element PE may also be regarded as a pattern element (or else as a pattern structure) of the EUV mask. The pattern element PE may be part of a designed pattern which can be transferred to a wafer, for example, via a lithography method. The local state D shows an opaque defect 1010 adjoining the pattern element PE. The opaque defect 1010 may feature, for example, excess (opaque) material that should not be present at the defect side after mask development. The excess (opaque) material may correspond, for example, to an opaque material of the pattern element PE, or else to any other material of a layer of the pattern element PE (as described herein). In relation to FIG. 1 (state D), a defect-free pattern element PE in the detail 1000 would have to have a square shape, but it is clear that this target state does not exist as a result of the opaque defect 1010. A repair procedure RV therefore removes the excess (opaque) material in the region of the opaque defect 1010, such that a repaired state R of the pattern element PE can be created. Thus, it is shown in state R that no opaque effect occurs any longer in the original defect region 1020 (i.e., at the original site in the opaque defect) and there is no longer any excess (opaque) material. The removal of the defect 1010 accordingly re-establishes the target state of the rectangular shape of the pattern element PE after a repair operation.

During use in lithography devices or lithography methods, a lithography mask may be subject to extreme physical and chemical environmental conditions. This is especially true of the exposure of EUV masks (and also DUV masks, or other masks as described herein) during a corresponding lithography method, in which the opaque material in particular of a pattern element PE may be subjected to these influences to a significant degree. For example, in the case of EUV exposure, a hydrogen plasma comprising free hydrogen radicals may be released, which can attack the opaque material of the pattern element PE among other materials and cause a material-altering and/or-removing effect. Further damage influences may occur in the EUV lithography process and mask cleaning processes. Damage to the mask material includes, for example, a chemical and physical alteration of the material by (EUV) radiation, temperature, and also a reaction with hydrogen or another reactive hydrogen species (e.g., free radicals, ions, plasma, etc.). The alteration of the material may also be caused by a reaction with purge gases (e.g., N2, extreme clean dry air—XCDA®, noble gases, etc.), in conjunction with the exposure radiation (e.g., EUV radiation, DUV radiation). The damage to the material may likewise arise or be enhanced by downstream processes (for example, a mask cleaning operation). The downstream processes may, for example, additionally attack the opaque material of the pattern element PE that has previously been damaged by chemical/physical reactions during the exposure operation, and hence worsen the damage.

Therefore, the specific opaque material used in a pattern element PE may be a chemically resistant material. In particular, iridium-containing materials (as described herein) may be employed as resistant material for the pattern element PE in an EUV mask on account of their very high chemical stability. The iridium-containing materials may, for example, take the form of IrₐZ_{b} (a, b≥0, Z: one or more further elements with the stoichiometric coefficient b applicable to the respective element). Z here may comprise a metal, nonmetal, semimetal, alkali metal (e.g., Li, Na, K, Rb, Cs). In addition, Z may comprise an alkaline earth metal (e.g., Be, Mg, Ca, Sr, Ba), a 3rd main group element (e.g., B, Al, Ga, In, Tl), a 4th main group element (e.g., C, Si, Ge, Sn, Pb), a 5th main group element (e.g., N, P, As, Sb, Bi). In addition, Z may comprise a chalcogenide (e.g., O, S, Se, Te), a halogen (e.g., F, Cl, Br, I) a noble gas (atom) (e.g., He, Ne, Ar, Kr, Xe), a transition group element (e.g., Ti, Hr, Hf, V, Nb, Ta, Cr, Mo, W, Mn, Re, Co, Rh, Ir, Ni, Pd, Pt, Cu, Ag, Au, Zn, Cd, Hg).

However, this type of resistance (opaque) material of a pattern element PE or of an EUV mask can make the repair operation RV of an opaque defect 1010 significantly more difficult since the repair operation is to specifically remove the resistant (opaque) material.

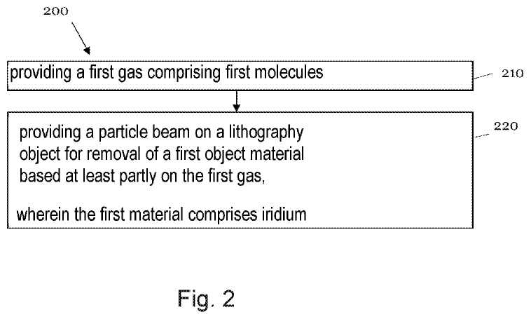

FIG. 2 shows a schematic diagram of an illustrative method 200 of the invention. The method 200 may be employed in order to remove material from an EUV mask. In particular, the method 200 may be employed in order to remove material from an opaque defect 1010 in the course of a repair operation.

The method 200 may comprise here providing 210 of a first gas including first molecules. The first gas here may comprise, for example, XeF₂ as first molecules. In addition, other gases are also conceivable as first gas, as described herein.

Other molecules are also suitable as first molecules of the first gas for the method 200. For example, polar and nonpolar triatomic molecules are conceivable. The first molecules may also comprise molecules that can be split into chlorine or fluorine radicals under suitable reaction conditions and/or additionally, for example, can be split into a further nonpolar species.

In addition, the method 200 may comprise providing 220 of a particle beam on the lithography object for removal of a first object material based at least partly on the first gas. The first material may comprise iridium. The method 200 may also comprise an electron beam as particle beam, such that electron beam-induced etching of the material by the method 200 may be enabled.

The first material may especially correspond to the resistant (opaque) material of the EUV mask (as described herein), which is to be removed in the course of the repair of an opaque defect.

The method 200 may also comprise providing a second gas as additive gas that assists the etching process (for example, with regard to etch selectivity, etch rate, anisotropy factor, etc.).

In particular, in the case of electron beam-induced etching, the first gas used in the method 200 may be XeF₂ and the additive gas H₂O (i.e., water (vapour)). In addition, the second molecules may comprise a dipole moment between 1.6 D and 2.1 D, preferably between 1.7 D and 2 D, more preferably between 1.8 D and 1.95 D, most preferably between 1.82 D and 1.9 D. It is also conceivable that H₂O is combined with nitrogen dioxide (or another oxidative gas) as additive gas.

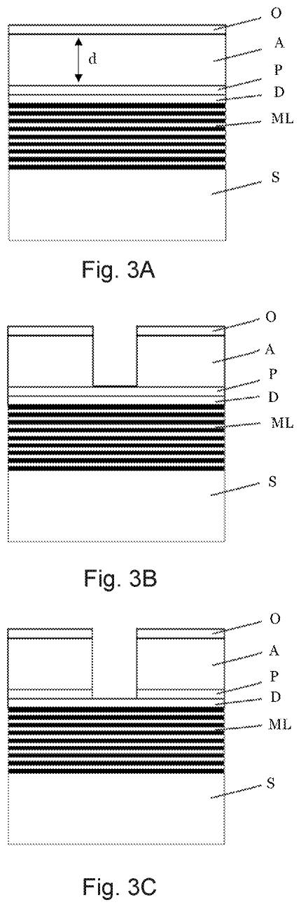

FIGS. 3A-3C give a schematic illustration, in a cross section, by way of example, of procedures in the method 200 that can take place in the course of repair of a defect in a lithography object.

FIG. 3A presents, in schematic form, an illustrative characteristic layer structure of a reflective lithography mask for the UV wavelength region (i.e., an UV mask). The illustrative EUV mask 200 may be designed, for example, for an exposure wavelength in the region of 13.5 nm. The EUV mask may include a substrate S made of a material with a low coefficient of thermal expansion, for example, quartz. Other dielectrics, glass materials or semiconducting materials likewise can be used as substrates for EUV masks.

The substrate S may be adjoined by a deposited multilayer film or a reflective layer stack ML including, for example, 20 to 80 pairs of alternating molybdenum (Mo) and silicon (Si) layers, which may also be referred to as MoSi layers. The individual layers of the multilayer film ML may differ in refractive index, giving rise to a Bragg mirror that can reflect incident radiation (e.g., EUV radiation).

In order to protect the reflective layer stack ML, a capping layer D may be applied, for example, atop the uppermost layer of the reflective layer stack ML. The capping layer D may protect the reflective layer stack ML from damage by chemical processes during the production and/or during the use of the EUV mask (for example, during a lithography method).

The capping layer D may comprise (elemental) ruthenium, and also elements or compounds of elements that increase reflectivity at wavelength 13.5 nm by not more than 3%. In addition, the capping layer D may comprise Rh, Si, Mo, Ti, TiO, TiO₂, ruthenium compounds, ruthenium alloys, ruthenium oxide, niobium oxide, RuW, RuMo, RuNb, Cr, Ta, nitrides, and also compounds and combinations of the aforementioned materials. The capping layer may further comprise one of the following materials: RuRh, RuZr, RuZrN, RuNbN, RuRhN, RuV, RuVN.

Atop the capping layer D there may be several layers that may include, for example, the layers of the pattern element (i.e., pattern element layers). The pattern element layers may comprise a buffer layer P, an absorption layer A and/or a surface layer O. The properties of the pattern element layers (for example, an intrinsic material property of a pattern element layer, a layer thickness of a pattern element layer, etc.) and the geometry of the pattern element PE shaped therefrom may be designed to cause an opaque effect in relation to the exposure wavelength of the EUV mask. For example, the pattern element PE may be designed such that it is opaque (i.e., non-transparent to light or highly light-absorbing) with respect to light radiation having a wavelength of 13.5 nm. The pattern element layers may correspond to the layers of the opaque defect 1010, although the opaque defect 1010 need not necessarily have all the pattern element layers. For example, the opaque defect 1010 may have merely the buffer layer P and the absorption layer A.

The buffer layer P may be present atop the capping layer D. In addition, the absorption layer A may be present atop the buffer layer P. The absorption layer A may be designed to be effective in absorbing the radiation of lithography wavelengths (as described herein). Accordingly, the absorption layer A may make the main contribution to an opaque effect of the pattern element (or of the opaque defect 1010). The optical properties of the absorption layer A can be described, for example, by a complex refractive index that may include a phase shift contribution (i.e., n) and the adsorption contribution (i.e., k). For example, n and k may be regarded as intrinsic material properties of the absorption layer. Only particular chemical elements and/or compounds of chemical elements have advantageous phase-shifting and/or absorptive properties for the corresponding lithography method (e.g., an EUV lithography method). FIG. 3A indicates, by way of example, the layer thickness d of the absorption layer A. The layer thickness d of the absorption layer A (and also a layer thickness of another layer of the mask) is ascertained, for example, along a normal vector in relation to the planar plane of the mask. In principle, it is also conceivable that the absorption layer A comprises multiple absorption layers including different materials, for example. In addition, the surface layer O may be present atop the absorption layer A. The surface layer O may comprise an antireflection layer, oxidation layer and/or passivation layer. As well as the absorption layer A, it is also possible for the buffer layer P and/or the surface layer O to contribute to the absorption and to the opaque effect of the pattern element PE or of the opaque defect 1010.

In principle, any of the pattern element layers described herein may include the resistant first material mentioned (i.e., iridium-containing material). Typically, for example, the absorption layer A includes iridium. The first material in the method 200 may accordingly comprise a material of the absorption layer A. In addition, it is alternatively possible, for example, for the buffer layer P or the surface layer O to include iridium and hence to constitute the first material in the method 200.

FIG. 3B shows a result of an illustrative method 200 for removal of part of the absorption layer A. In this example, the absorption layer A is designed as the first material in the method 200. Initially, part of the surface layer O may first be removed. For example, this can be effected analogously to the method 200 via electron beam-induced etching in a separate step. The surface layer need not necessarily be removed with the first and/or second gas (as described herein). It is also conceivable that the electron beam-induced etching is designed exclusively for the removing of the surface layer O (for example, with an etching gas matched to the material of the surface layer). After the surface layer O has been removed, it is then possible to remove part of the absorption layer A as the first material in the method 200 (for example, to repair an opaque defect). FIG. 3B illustrates selective electron beam-induced etching of the absorption layer A with respect to the buffer layer P. Accordingly, the method 200 may be adjusted such that the etch rate of the absorption layer A is elevated compared to the etch rate of the buffer layer P. For example, the etching selectivity can be adjusted via the properties of the second gas in the method 200 (for example, via a suitable choice of the second gas (e.g., water), or the gas flow rate of the second gas). In addition, the etch selectivity can also be adjusted by the properties of the first gas (for example, via the choice of first gas (e.g., XeF₂), or via the gas volume flow rate of the first gas). In this example, the buffer layer P accordingly functions as etch stop via the etch selectivity chosen. In the example of FIG. 3B, the buffer layer P may constitute the second material which is essentially not removed.

FIG. 3C shows a further result of an illustrative method 200 for removal of part of the absorption layer A. Initially, it is possible here (as described herein) to remove a portion of the buffer layer O. After the surface layer O has been removed, it is then possible to remove part of the absorption layer A as the first material in the method 200. It is also possible here to etch a portion of the buffer layer P as intermediate material. Accordingly, the method 200 may be adjusted such that the etch rate of the absorption layer A, and also the etch rate of the buffer layer P, are elevated compared to the etch rate of the capping layer D. The etch rate of the absorption layer A may be in the same order of magnitude as the etch rate of the buffer layer P. The etch selectivity may be adjusted as described herein. As shown in FIG. 3C, this can achieve selective electron beam-induced etching of the absorption layer A and of the buffer layer P with respect to the capping layer D. In this example, the capping layer D therefore functions as etch stop via the etch selectivity chosen. In the example of FIG. 3C, the capping layer D may thus constitute the second material which is essentially not removed.

In one example, the surface layer O is not removed separately, but via the same process which is employed for the local removing of the absorption layer A (or of the absorption layer A and the buffer layer P) in a method 200.

It should also be mentioned that the parameter space (e.g., gas parameters of the first/second gas, particle beam parameters) of the method 200 may depend firstly on the layer currently being processed (by the particle beam). This may correspond, for example, to stepwise removal of layers (or materials), with adjustment of the parameter space of the method 200 for each layer (or each of the materials). However, it is also possible that the parameter space of the method 200 does not depend on the layer currently being processed (with the particle beam). This approach too can, for example, remove multiple layers (or materials) successively.

It should also be mentioned that the first material (comprising iridium) may be any layer material in the EUV mask. For example, the capping layer D may comprise iridium. By the approach described herein, it is also possible to etch such an iridium-containing capping layer D.

The method 200 (or the method in the first aspect) may be executed via the device of the invention described herein. In one example, the device comprises a mask repair device for repair or processing of lithography masks. The device may be used to localize and to repair or remedy mask defects. The device may comprise parts such as the device described in US 2020/0103751 A1 (see the corresponding FIG. 3A therein). The device may comprise, for example, a control unit which may, for example, be part of a computer system. The device, in one example, may be configured such that the computer system and/or the control unit controls the process parameters of the method in the first aspect as disclosed herein. This configuration can enable controlled, and also automated, implementation of the method according to the invention as specified herein, for example without manual interventions. This configuration of the device can be achieved or enabled, for example, via the computer program according to the invention as described herein.

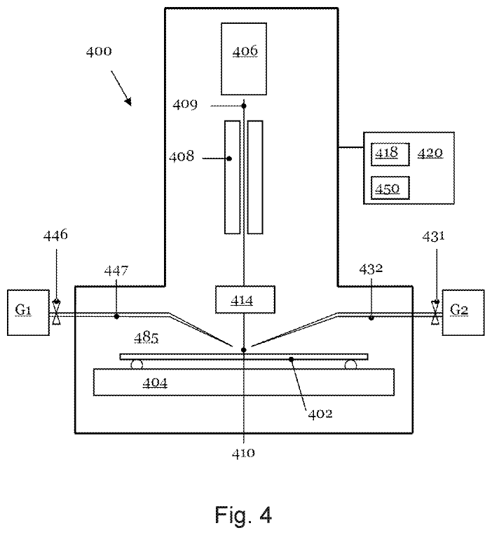

FIG. 4 shows a schematic section of an illustrative device 400 according to the invention. The device 400 may be configured, for example, such that it can perform the method 200 or a method in the first and/or second aspect of the invention. For example, it is possible for a corresponding computer program (as described herein) to be programmed on the device.

In one example, the device 400 of FIG. 4 comprises a mask repair device for repair or processing of lithography masks. The device 400 may be used, for example, to localize and to repair or remedy mask defects.

The illustrative device 400 of FIG. 4 may comprise, for example, a scanning electron microscope (SEM) 101 for provision of a particle beam, which, in this example, is an electron beam 409. An electron gun 406 can generate the electron beam 409, which can be directed by one or more beam-forming elements 408 as a focussed electron beam 110 onto a lithography mask 402, which is arranged on a sample stage 404 (or chuck). In addition, the scanning electron microscope can be used to control parameters/properties of the electron beam (e.g., acceleration voltage, dwell time, current, focusing, spot size, etc.) The parameters of the electron beam may be adjusted, for example, in relation to a parameter space of the methods described herein. The electron beam 409 may serve as an energy source for initiating a local chemical reaction in a working region of the lithography mask 402. This may be utilized, for example, for the methods described herein (for example, for the implementation of the electron beam-induced etching in the first aspect). In addition, the electron beam 409 may be utilized for imaging of the lithography mask 102. The device 400 may comprise here one or more detectors 414 for detecting electrons (for example, secondary electrons, backscattered electrons).

In order to conduct the corresponding methods specified herein, the illustrative device 400 of FIG. 4 may include at least two reservoir vessels for at least two different processing gases or precursor gases. The first reservoir vessel G1 may store the first gas. The second reservoir vessel G2 may store the second gas. In some examples, the temperatures of reservoir vessels G1 and G2 may be controlled independently of one another. The second gas may also be regarded as an additive gas. In addition, in the illustrative device 400, each reservoir vessel G1, G2 has its own gas inlet system 432, 447, which can end with a nozzle close to the point of incidence of the electron beam 410 on the lithography mask 402. It is possible for each reservoir vessel G1, G2 to have its own control valve 446, 431 in order to control the amount of the corresponding gas provided per unit time, i.e., the gas flow rate of the corresponding gas. This can be effected in such a way that the gas volume flow rate is controlled at the point of incidence of the electron beam 410. In addition, the device 400, in one example, may include further reservoir vessels for additional gases that can be added to the method in the first aspect as one or more (additive) gases (e.g., oxidizing agent, reducing agent, halides as described herein). The device 400 in FIG. 4 may include a pump system for generating and maintaining a pressure required in the process chamber 485.

The device 400 may also comprise a (closed-loop) control unit 418 which may, for example, be part of a computer system 420. The device 400, in one example, may be configured such that the computer system 420 and/or the control unit 418 controls the process parameters of the methods disclosed herein. This configuration can enable controlled or automated implementation of the methods according to the invention as specified herein, for example, without manual interventions. This configuration of the device 400 can be achieved or enabled, for example, via the computer program according to the invention as described herein.

For example, the device 400 may comprise a memory 450 in which the computer program in the fourth aspect as described herein is stored. For example, the computer system 420 may cause the instructions stored in the memory 450 to be executed, such that a first material comprising iridium is removed according to the invention by use of the device (with the necessary process parameters). The device may comprise, for example, an interface. The interface may receive the information that a method is to be executed, in which the first material (described herein) is to be removed. For example, an input may be effected by an operator via the interface that an iridium-containing material is to be removed. Based on this information, the device may cause the computer program in the fourth aspect to be called up from the memory 450, such that the method in the first aspect is executed.

What is claimed is:

1. A method of processing a lithography object, comprising:
providing a first gas comprising first molecules;
providing a particle beam on the object for removal of a first object material based at least partly on the first gas,
wherein the first material comprises iridium.

2. The method of claim 1, wherein the first gas is provided locally on the object.

3. The method of claim 1, wherein the first material comprises a layer material on the object.

4. The method of claim 1, wherein the first material comprises a layer material of a pattern element on the object.

5. The method of claim 1, wherein the first material comprises a radiation-absorbing and/or phase-shifting layer material on the object.

6. The method of claim 1, wherein the first molecules comprise a halogen atom.

7. The method of claim 6, wherein the halogen atom comprises at least one of the following: fluorine, chlorine, bromine, or iodine.

8. The method of claim 1, wherein the first molecules comprise a halogen compound.

9. The method of claim 1, wherein the first molecules comprise a noble gas halide.

10. The method of claim 9, wherein the noble gas halide comprises at least one of the following: xenon difluoride, XeF₂, xenon dichloride, XeCl₂, xenon tetrafluoride, XeF₄, or xenon hexafluoride, XeF₆.

11. The method of claim 1, wherein the first material does not comprise ruthenium.

12. The method of claim 1, wherein:
the iridium content of the first material comprises at least 50 atom percent, at least 70 atom percent, at least 80 atom percent, or at least 90 atom percent; and/or
the iridium content of the first material comprises at most 90 atom percent, at most 80 atom percent, at most 70 atom percent, at most 60 atom percent, at most 50 atom percent or at most 40 atom percent.

13. The method of claim 1, wherein the first material further comprises at least a second element.

14. The method of claim 13, wherein the second element comprises at least one of the following: a metal or a semiconductor.

15. The method of claim 13, wherein the second element comprises at least one of the following:
tantalum, ruthenium, or antimony.

16. The method of claim 13, wherein the second element comprises at least one nonmetal.

17. The method of claim 13, wherein the second element comprises oxygen and/or nitrogen.

18. The method of claim 1, wherein the method further comprises:
providing a second gas comprising second molecules, wherein the removing of the first material is also based at least partly on the second gas.

19. The method of claim 18, wherein a dipole moment of the second molecules comprises a value between 1.6 D and 2.1 D, preferably between 1.7 D and 2 D, more preferably between 1.8 D and 1.95 D, most preferably between 1.82 D and 1.9 D.

20. The method of claim 18, wherein the second molecules comprise water and/or heavy water.

21. The method of claim 1, wherein the first material is removed selectively, such that a second material of the object is essentially not removed.

22. The method of claim 21, wherein the method comprises removing at least one intermediate material disposed between the first material and the second material.

23. The method of claim 21, wherein the method comprises removing at least one surface material of the object.

24. The method of claim 1, wherein the method is effected in such a way that a defect of the object is repaired.

25. The method of claim 1, wherein the object comprises an EUV mask and/or a DUV mask.

26. A lithography object, wherein the object has been processed by a method according to claim 1.

27. A method of processing of a semiconductor-based wafer, comprising:
lithographic transfer of a pattern associated with a lithography object to the wafer,
wherein the object has been processed by a method according to claim 1.

28. A computer program comprising instructions for performing a method according to claim 1.

29. A device for processing a lithography object, comprising:
means of providing a first gas;
means of providing a particle beam on the object; and
memory comprising a computer program which, when executed, causes the device to perform a method according to claim 1.
